(19) United States
(12) Patent Application Publication
(10) Pub. No.: US 2010/0237493 A1
(43) Pub. Date: Sep. 23, 2010

(54) PRINTED CIRCUIT BOARD AND ELECTRONIC APPARATUS HAVING A PRINTED CIRCUIT BOARD

(75) Inventor: Takahiro SUGAI, Kokubunji-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/684,028

(22) Filed: Jan. 7, 2010

(30) Foreign Application Priority Data
Mar. 17, 2009 (JP) 2009-065060

(51) Int. Cl. H01L 23/488

(52) U.S. Cl. 257/692; 257/738; 257/690; 257/E23.023

(57) ABSTRACT

A printed circuit board including: a semiconductor package including a main body including a substantially rectangular parallelepiped shape, and a plurality of solder balls on one face of the main body; a board including a first face, a second face, and a hole portion, the first face including a mounting area where the plurality of solder balls are configured to be attached, the second face being opposite to the first face, the hole portion being formed around the mounting area and connected to a conductive pattern, the conductive pattern being configured to be connectable to an electronic component mounted on the board; and a bonding portion configured to bond the semiconductor package to the board, the bonding portion including a portion disposed in the hole portion.

### CROSS-REFERENCE TO RELATED APPLICATIONS

This application is based upon and claims the benefit of priority from Japanese Patent Application No. 2009-065060, filed on Mar. 17, 2009, the entire contents of which are incorporated herein by reference.

### BACKGROUND

1. Field

An aspect of the present invention relates to a printed circuit board in which a semiconductor package is bonded to a board with bonding portions and to an electronic apparatus having such a printed circuit board.

2. Description of the Related Art

Among printed circuit boards used in portable computers are ones incorporating a semiconductor package of ball grid array (BGA) or chip sized package (CSP). In the BGA in which a semiconductor package is bonded to a board via plural solder balls, in addition to the solder balls a structure for fixing the semiconductor package to the board may be used to secure sufficient reliability of the connections.

Various structures are disclosed as the above structure for fixing a semiconductor package to a board. For example, a fixing structure is known in which a prescribed portion of a semiconductor package is coated with a bonding portion. Furthermore, a technique is disclosed in which that portion of a board that is adjacent to the outer circumference of a mounting area and that is coated with such a bonding portion is additionally provided with a projection/recess portion where rectangular or V-shaped projections and recesses are arranged, whereby the bonding area of the bonding portion and the board is increased (see JP-A-2008-153583, for instance).

In order to provide the fixing structure, the projection/recess portion needs to be additionally formed on the board, which is laborious. Further, the projection/recess portion is merely for enlarging the bonding area and does not have other function.

### BRIEF DESCRIPTION OF THE SEVERAL VIEWS OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 is an exemplary perspective view of a portable computer according to each embodiment of the present invention;

FIGS. 2A and 2B show an exemplary printed circuit board (before coated with bonding portions) according to a first embodiment of the invention;

FIGS. 3A and 3B show an exemplary printed circuit board (after coated with the bonding portions) according to the first embodiment of the invention;

FIGS. 4A to 4F are exemplary sectional views showing a manufacturing process of the printed circuit board according to the first embodiment of the invention;

FIGS. 5A and 5B show an exemplary printed circuit board (before coated with bonding portions) according to a second embodiment of the invention;

FIGS. 6A and 6B show exemplary printed circuit board (after coated with the bonding portions) according to the second embodiment of the invention;

FIGS. 7A to 7F are exemplary sectional views showing a manufacturing process of the printed circuit board according to the second embodiment of the invention;

FIG. 8 is an exemplary top view showing a printed circuit board (after coated with bonding portions) according to a modification of the second embodiment of the invention.

### DETAILED DESCRIPTION

Various embodiments according to the present invention will be described hereinafter with reference to the accompanying drawings. In general, according to one embodiment of the present invention, there is provided a printed circuit board including: a semiconductor package including a main body including a substantially rectangular parallelepiped shape, and a plurality of solder balls on one face of the main body; a board including a first face, a second face, and a hole portion, the first face including a mounting area where the plurality of solder balls are configured to be attached, the second face opposite to the first face, the hole portion provided around the mounting area and connected to a conductive pattern, the conductive pattern connectable to an electronic component mounted on the board; and a bonding portion configured to bond the semiconductor package to the board, the bonding portion including a portion disposed in the hole portion.

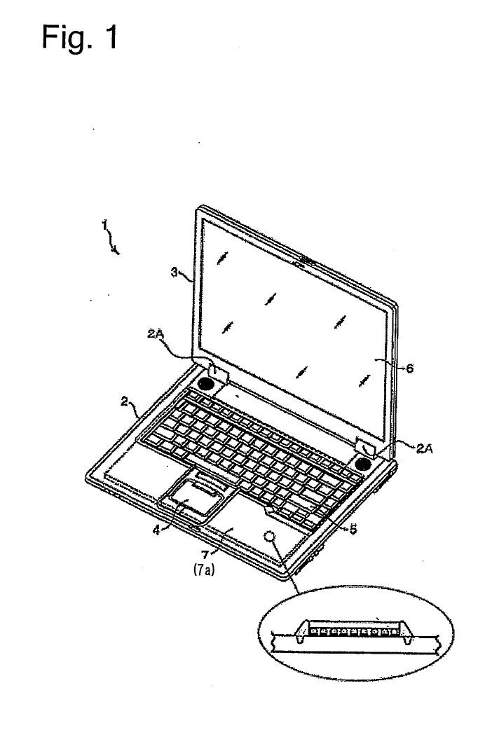

Embodiments of the printed circuit board according to the present invention will be hereinafter described with reference to FIGS. 1 to 8. The embodiments are directed to a case that the invention is applied to a portable computer which is an example of an electronic apparatus.

First, a first embodiment of the invention will be described with reference to FIGS. 1 to 4F. FIG. 1 is a perspective view of a portable computer 1 according to each embodiment of the invention. As shown in FIG. 1, a display unit casing 3 is attached rotatably to a main body 2 of the portable computer 1 via hinge mechanisms 2A. The main body 2 is equipped with operation units such as a pointing device 4 and a keyboard 5. The display unit casing 3 is equipped with a display device 6 such as a liquid crystal display (LCD).

The main body 2 is also equipped with a printed circuit board (mother board) 7 or 7a which incorporates control circuits for controlling the operation units such as the pointing device 4 and the keyboard 5 and the display device 6.

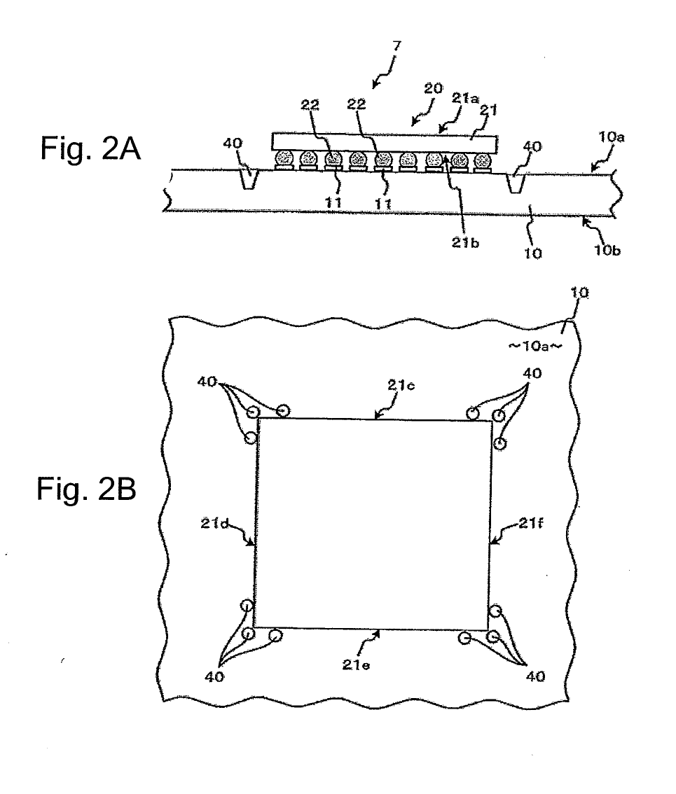

FIGS. 2A and 2B show the printed circuit board 7 (before coated with bonding portions 30) according to the first embodiment of the invention. FIGS. 2A and 2B are a sectional view and a top view, respectively, of the printed circuit board 7. The printed circuit board 7 includes a board 10 and a semiconductor package 20.

The board 10 has a first face 10a and a second face 10b. The first face 10a of the board 10 is provided with plural pads 11 at such positions that they are opposed to respective solder balls 22 of the semiconductor package 20 (described later). The area of the first face 10a where the pads 11 are provided corresponds to a mounting area according to the invention. The board 10 may be either a single-layer board or a multilayer board. The board 10 may also have interconnections and electrodes on the first face 10a and the second face 10b as well as in internal layers (in the case of a multilayer board). The first face 10a and the second face 10b may be coated with a solder resist.

The semiconductor package 20 has a package main body 21 substantially shaped like a rectangular parallelepiped, for example, and the plural solder balls 22 that project from one face of the package main body 21. That is, the package main body 21 has a top face 21a, a bottom face 21b which is opposed to the top face 21a, and side faces 21c, 21d, 21e, and 21f which surround peripheries of the top face 21a and the bottom face 21b. The package main body 21 is thus substantially shaped like a flat, rectangular parallelepiped. The semiconductor package 20 is a BGA or CSP semiconductor package, for example.

The first face 10a of the board 10 according to the first embodiment of the invention is provided with vias 40. The vias 40 correspond to hole portions according to the invention. As shown in FIG. 2A, the depth of the vias 40 in the thickness direction of the board 10 is such that the vias 40 do not penetrate through the board 10. As shown in FIG. 2B, three vias 40 are provided around, that is, in or next to each of the four corners of the package main body 21. To connect wiring patterns in desired layers of a board having two or more wiring layers, the inside face of each via 40 is conductive because it was subjected to electroless copper plating, for example. The diameter of the via 40 is small but is sufficient to connect conductors in layers of a double-sided printed wiring board or a multilayer printed wiring board.

Although in the first embodiment the vias 40 are provided around each of the four corners of the package main body 21, the invention is not limited to the case that the vias 40 are provided around the four corners. Although in the embodiment, three vias 40 are provided around each of the four corners of the package main body 21, any number of vias 40 may be provided around each corner. Furthermore, the invention is not limited to the case that vias 40 are provided around each corner of the package main body 21; the only requirement is that the vias 40 be provided adjacent to the outer circumference of the semiconductor package 20 mounting area. For example, vias 40 may be provided in the first face 10a of the board 10 adjacent to the middle points of the side faces 21c-21f of the semiconductor package 20.

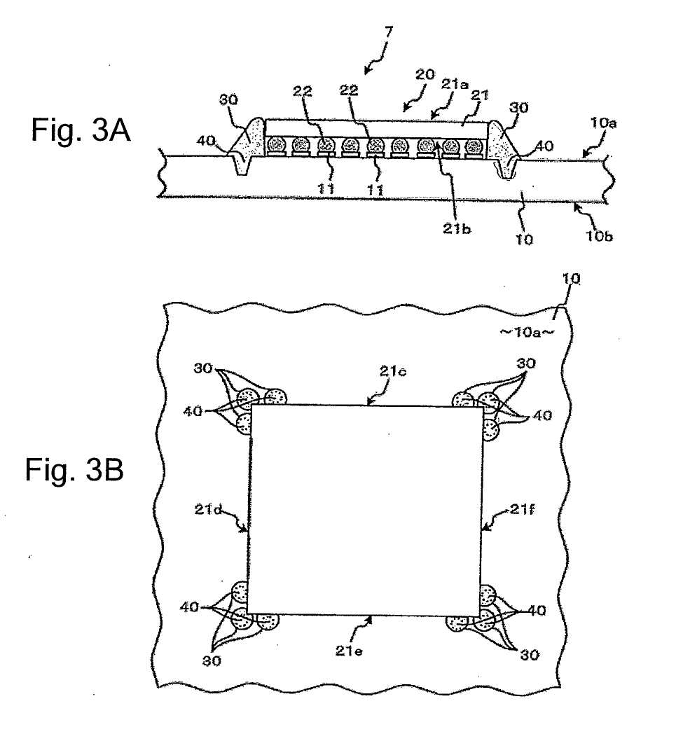

Next, a structure in which the printed circuit board 7 is coated with bonding portions 30 will be described with reference to FIGS. 3A and 3B. FIGS. 3A and 3B show the printed circuit board 7 (after coated with the bonding portions 30) according to the first embodiment of the invention. FIGS. 3A and 3B are a sectional view and a top view, respectively, of the printed circuit board 7 (after coated with the bonding portions 30).

The bonding portions 30 bond the semiconductor package 20 to the board 10. Usually, the bonding portions 30 are made of a thermosetting resin. Instead of a thermosetting resin, a two-liquid-mixing-type resin, a resin that is set when illuminated with ultraviolet (UV) light or the like, or a resin whose setting is accelerated by spraying a curing agent on it after its application may be used. It is preferable that the bonding portions 30 be insulative.

In the first embodiment, as shown in FIG. 3B, bonding portions 30 are applied around (in or next to) each corner of the package main body 21 so as to cover the respective vias 40 that is indicated by dotted lines. That is, instead of being applied so as to cover an annular area adjacent to the entire outer circumference of the package main body 21, the bonding portions 30 are applied in restricted areas to avoid sealing the space between the package main body 21 and the board 10 airtightly. This is to prevent a phenomenon that the sealed-in air expands and damages the package main body 21 during heat treatment for bonding with the solder balls 22 and the bonding portions 30. It is thus desirable that the bonding portions 30, which bond the semiconductor package 20 to the board 10, not be applied to at least one portion of the outer circumference of the package main body 21 to form an opening below that at least one portion.

As shown in FIG. 3A, the bonding portions 30 that are applied at positions corresponding to the respective vias 40 are charged into the respective vias 40. As a result, the bonding area of each bonding portion 30 and the board 10 is increased and hence the bonding strength is increased.

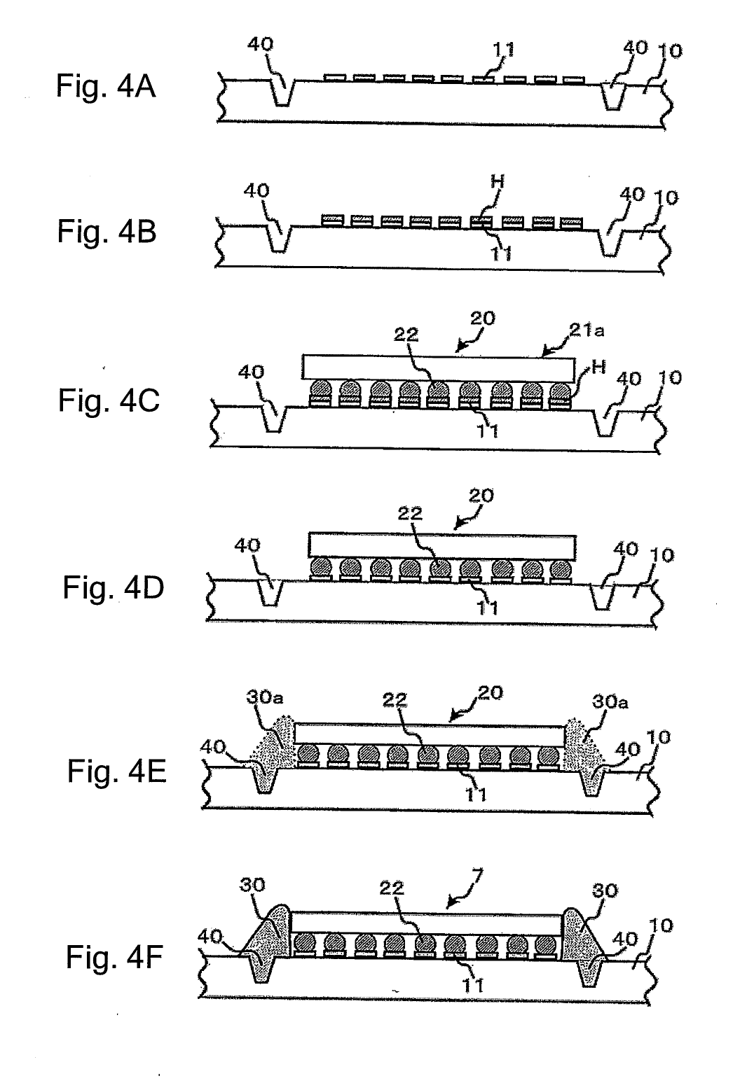

Next, a manufacturing method of the printed circuit board 7 according to the first embodiment will be described with reference to FIGS. 4A to 4F. FIGS. 4A to 4F are sectional views showing a manufacturing method of the printed circuit board 7 according to the first embodiment of the invention.

First, at step S1, as shown in FIG. 4A, a board 10 to be mounted with a semiconductor package 20 and having plural pads 11 and vias 40 are prepared (board preparing step).

At step S2, as shown in FIG. 4B, each pad 11 is coated with solder paste H (solder applying step). In the solder applying step, the board 10 is mounted with a metal mask which has openings at positions corresponding to areas where solder should be applied, solder paste H is applied from above the metal mask, and the solder paste H on the metal mask is extended uniformly with a tool such as a squeegee. As a result, the solder paste H is applied to the pads 11 through the openings of the metal mask.

At step S3, as shown in FIG. 4C, the semiconductor package 20 is mounted on the board 10 (mounting step). More specifically, the semiconductor package 20 is moved to such a position that the solder balls 22 are opposed to the respective pads 11 with the top face 21a of the semiconductor package 20 absorbed by a mounting machine such as a mounter, and the semiconductor package 20 is mounted on the board 10 with the mounting machine.

At step S4, as shown in FIG. 4D, the board 10 which is mounted with the semiconductor package 20 is heated, whereby solder bonding is carried out (first heating step). In this heating step, heat treatment having a prescribed temperature profile is performed by using a reflow furnace, for example. The semiconductor package 20 is bonded to the board 10 as the solder paste H is integrated with the solder balls 22.

At step S5, as shown in FIG. 4E, thermosetting bonding portions 30 are applied (bonding portions applying step). More specifically, each bonding portion 30 is applied to the board 10 and a side face of the package main body 21. The bonding portions 30 that have not been set or heated are shown as bonding portions 30a in FIG. 4E. The bonding portions 30 are charged into the respective vias 40 which are formed in the first face 10a of the board 10.

At step S6, as shown in FIG. 4F, the bonding portions 30 are set by heating the board 10 (second heating step). As the bonding portions 30 are set, the semiconductor package 20 is bonded to the board 10 there.

A printed circuit board 7 in which the bonding portions 30 are charged in the respective vias 40 is thus obtained as a result of the execution of steps S1 to S6.

According to the above-described first embodiment, the vias 40 which are provided to connect wiring patterns can be utilized for increasing the bonding area of each bonding portion 30 which serves to bond the package main body 21 to the board 10. That is, the bonding area of each bonding portion 30 can be increased by forming the vias 40 alongside the outer circumference of the semiconductor package 20 mounting area at positions corresponding to the respective bonding portion 30 application positions. Exhibiting an anchoring effect, the bonding portions 30 which are charged in the respective vias 40 are not prone to peel away. The reliability of the connection of the solder bonding portions of the semiconductor package 20 is thus increased. Furthermore, the vias 40 can serve as application position targets when the bonding portions 30 are applied, whereby the work efficiency is increased.

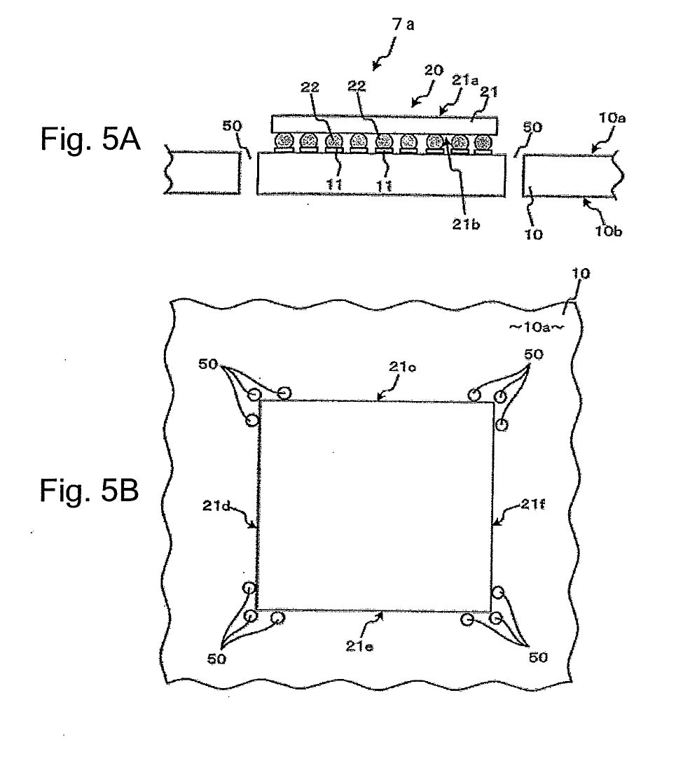

A second embodiment of the invention will be described below with reference to FIGS. 5A to 7F. FIGS. 5A and 5B show a printed circuit board 7a (before coated with the bonding portions 30) according to the second embodiment of the invention. The second embodiment is different from the first embodiment in that through-holes 50 are formed in a substrate 10.

As shown in FIG. 5A, the through-holes 50 penetrate through the substrate 10 in its thickness direction. As shown in FIG. 5B, three through-holes 50 are provided around (in or next to) each of the four corners of the package main body 21. To connect wiring patterns in desired layers of a board having two or more wiring layers, the inside face of each through-hole 50 is conductive because it was subjected to electroless copper plating, for example. The diameter of the through-holes 50 is small but is sufficient to connect conductors in layers of a double-sided printed wiring board or a multilayer printed wiring board.

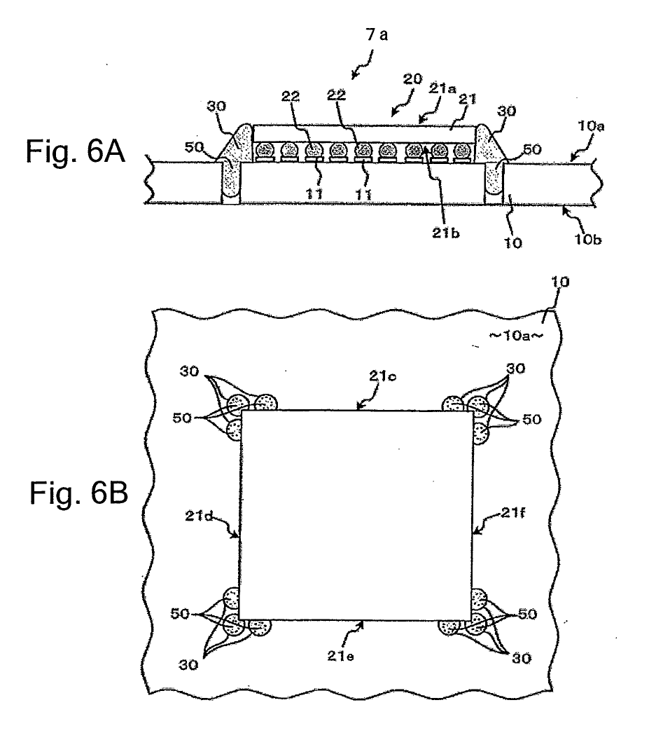

Next, a structure in which the printed circuit board 7a is coated with bonding portions 30 will be described with reference to FIGS. 6A and 6B. FIGS. 6A and 6B show the printed circuit board 7a (after coated with the bonding portions 30) according to the second embodiment of the invention. FIGS. 6A and 6B are a sectional view and a top view, respectively, of the printed circuit board 7a (after coated with the bonding portions 30).

In the second embodiment, as shown in FIG. 6B, bonding portions 30 are applied around each corner of the package main body 21 so as to cover the respective through-holes 50 (indicated by dotted lines). When the bonding portions 30 are applied at positions corresponding to the respective through-holes 50, parts of the bonding portions 30 remain in the respective through-holes 50 as shown in FIG. 6A, because the bonding portions 30 are made of a viscous material and the through-holes 50 are small in diameter. Since the bonding portions 30 are charged in the inside spaces of the through-holes 50, the bonding area of each bonding portion 30 and the board 10 is increased and hence the bonding strength is increased. Furthermore, exhibiting an anchoring effect, the bonding portions 30 which are charged in the respective through-holes 50 increase the bonding strength further.

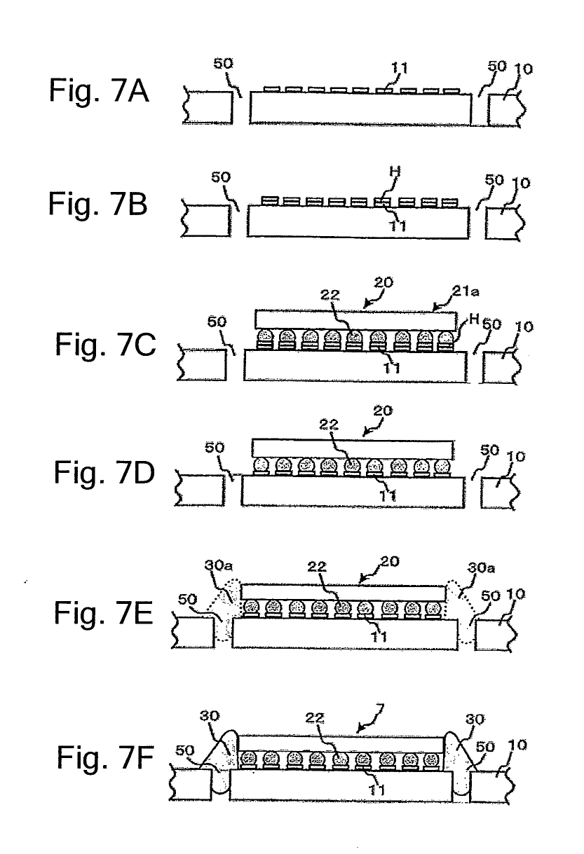

Next, a manufacturing method of the printed circuit board 7a according to the second embodiment will be described with reference to FIGS. 7A to 7F. FIGS. 7A to 7F are sectional views showing a manufacturing method of the printed circuit board 7a according to the second embodiment of the invention.

The manufacturing method of the printed circuit board 7a according to the second embodiment is different from that of the printed circuit board 7 according to the first embodiment in that the holes that are formed in the board 10 which is prepared at step S1 are through-holes 50.

First, at step S1, as shown in FIG. 7A, a board 10 to be mounted with a semiconductor package 20 and having plural pads 11 and through-holes 50 are prepared (board preparing step).

The subsequent steps are the same as in the manufacturing method of the printed circuit board 7 according to the first embodiment and hence will not be described. A printed circuit board 7a in which the bonding portions 30 are charged in the respective through-holes 50 is obtained as a result of the execution of steps S1 to S6.

According to the above-described second embodiment, the through-holes 50 which are provided to connect wiring patterns can be utilized for increasing the bonding area of each bonding portion 30 which serves to bond the package main body 21 to the board 10. That is, the bonding area of each bonding portion 30 can be increased by forming the through-holes 50 alongside the outer circumference of the semiconductor package 20 mounting area at positions corresponding to the respective bonding portion 30 application positions. Exhibiting an anchoring effect, the bonding portions 30 which are charged in the respective through-holes 50 are not prone to peel away. The reliability of the connection of the solder bonding portions of the semiconductor package 20 is thus increased. Furthermore, the through-holes 50 can serve as application position targets when the bonding portions 30 are applied, whereby the work efficiency is increased.

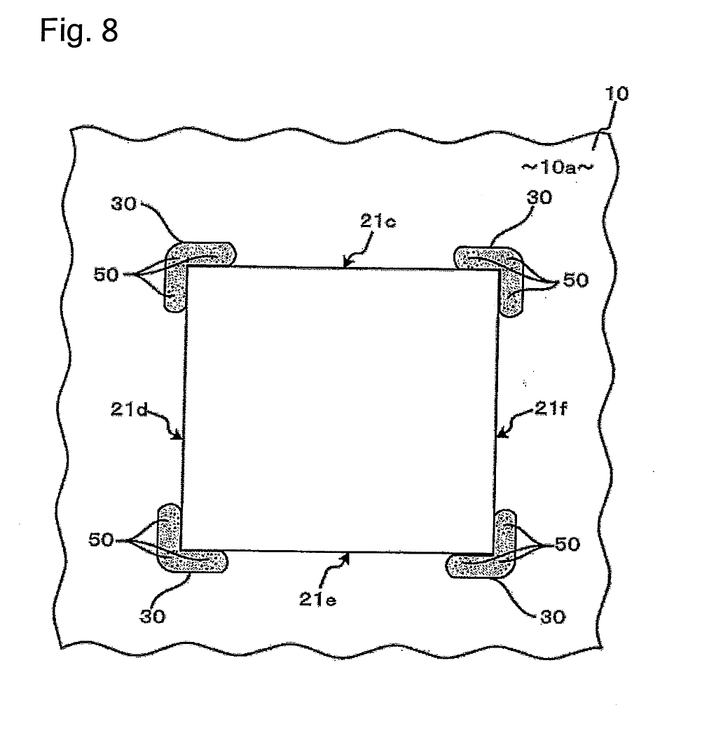

Next, a modification of the second embodiment will be described with reference to FIG. 8. FIG. 8 is a top view showing a printed circuit board (after coated with bonding portions 30) according to the modification of the second embodiment of the invention.

The modification is different from the second embodiment in the application positions of the bonding portions 30. Although in the second embodiment three bonding portions 30 are applied at positions corresponding to the respective through-holes 50 that are associated with each corer of the package main body 21, the invention is not limited to such a case. As in the modification of the second embodiment, a continuous bonding portion 30 may be applied in L-shaped form around each corner of the package main body 21.

The modification of the second embodiment provides the same advantages as the second embodiment.

The invention is not limited to the above embodiments themselves and, in the practice stage, may be embodied in such a manner that constituent elements are modified without departing from the spirit and scope of the invention. And various inventions can be conceived by properly combining plural constituent elements disclosed in each embodiment. For example, several ones of the constituent elements of each embodiment may be omitted. Furthermore, constituent elements of different embodiments may be combined as appropriate.

What is claimed is:

1. A printed circuit board comprising:
a semiconductor package comprising a main body comprising a plurality of solder on one face of the main body;
a board comprising a first face comprising a mounting area for the plurality of solder, a second face being opposite to the first face, and one or more holes positioned substantially near the mounting area and comprising a conductive pattern, the conductive pattern electrically connectable; and
one or more attachments located at or near the one or more holes to attach the semiconductor package to the board.

2. The printed circuit board of claim 1, wherein at least one of the one or more holes are located substantially near the mounting area and at or adjacent to at least one of corners of the main body.

3. The printed circuit board of claim 2, wherein:
The one or more holes comprises a plurality of hole portions; and
the plurality of hole portions are formed around the mounting area and in or next to a corner of the main body.

4. The printed circuit board of claim 3, wherein the one or more holes are configured to penetrate the board from the first face to the second face.

5. An electronic apparatus comprising:
a casing; and
a printed circuit board in the casing, the printed circuit board comprising:
a semiconductor package comprising a main body comprising a plurality of solder on one face of the main body;
a board comprising a first face comprising a mounting area, a second face being opposite to the first face, and one or more holes substantially near the mounting area, a surface of the one or more holes being covered with a conductive member that is connected to a conductive pattern, the conductive pattern being configured to be connectable to an electronic component mounted on the board; and
one or more attachments located at or near the one or more holes to attach the semiconductor package to the board.

6. The electronic apparatus of claim 5, wherein the one or more holes are provided substantially near the mounting area and is at or next to at least one of corners of the main body.

7. The electronic apparatus of claim 6, wherein:
the one or more hole portions comprises a plurality of hole portions; and
the plurality of hole portions are formed substantially near the mounting area and at or adjacent to a corner of the main body.

8. The electronic apparatus of claim 7, wherein the one or more holes are configured to penetrate the board from the first face to the second face.
